(19) United States
(12) Patent Application Publication
(10) Pub. No.: US 2021/0223834 A1
(43) Pub. Date: Jul. 22, 2021

(54) DISPLAY PANEL

(71) Applicant: Wuhan China Star Optoelectronics Semiconductor Display Technology Co., Ltd., Wuhan, Hubei (CN)

(72) Inventor: Kunyueh TSAI, Wuhan, Hubei (CN)

(73) Assignee: Wuhan China Star Optoelectronics Semiconductor Display Technology Co., Ltd., Wuhan, Hubei (CN)

(21) Appl. No.: 17/051,439

(22) PCT Filed: Mar. 15, 2019
(86) PCT No.: PCT/CN2019/078353

§ 371 Date: Oct. 29, 2020

(30) Foreign Application Priority Data
Dec. 18, 2018 (CN) 201811549968.4

(51) Int. Cl. G06F 1/18

(52) U.S. Cl. CPC G06F 1/186; G06F 1/189

(57) ABSTRACT

The present disclosure discloses a peripheral area part of a display panel including a chip connection area. The chip connection area includes at least two input signal connection pads and at least six output signal connection pads. The at least two input signal connection pads are arranged in an array along a first direction. The at least six output signal connection pads are arranged in three columns along a second direction. The at least six output signal connection pads are arranged in at least two rows along the first direction. The present disclosure can adapt to various types of chips.

### BACKGROUND

### Field

The present disclosure relates to a technical field of display devices, and more particularly to display panels.

### Background

Traditional display panels are generally provided with connection pads, chips are arranged on the display panel, and the chips are connected with the display panel through the connection pads.

In practice, at least the following technical problems are found in the prior art.

A connecting area corresponding to a chip on the display panel only adapts to a chip with a single pin type, but the connecting area cannot adapt to chips with different pin types.

Therefore, it is required to provide a new technical scheme to solve the above-mentioned technical problems.

### SUMMARY OF THE DISCLOSURE

The disclosure aims to provide a display panel which can adapt to various types of chips.

In order to solve the above-mentioned technical problems, technical schemes of the disclosure are provided as follows.

In an embodiment of the display panel, a display panel includes a display area part and a peripheral area part, wherein the peripheral area part is provided with a chip connection area, and the chip connection area includes an input signal connection pad array and an output signal connection pad array; wherein the input signal connection pad array is disposed on one side of the chip connection area, and the output signal connection pad array is disposed on the other side of the chip connection area; wherein the input signal connection pad array includes at least two input signal connection pads, and the at least two input signal connection pads are arranged in an array along a first direction; wherein the output signal connection pad array includes at least six output signal connection pads, the at least six output signal connection pads are arranged in three columns along a second direction that is perpendicular to the first direction, and the at least six output signal connection pads are arranged in at least two rows along the first direction; wherein a summation of a width of a gap between two adjacent output signal connection pads and a width of an output signal connection pad is in a range from 20 microns to 36 microns along the first direction; wherein a number of the output signal connection pads in a column of the output signal connection pads is in a range from 900 to 1020 along the first direction.

In an embodiment of the display panel, the summation of the width of the gap between two adjacent output signal connection pads and the width of the output signal connection pad is 28 microns along the first direction.

In an embodiment of the display panel, the width of the gap between two adjacent output signal connection pads is in a range from 10 microns to 18 microns along the first direction.

In an embodiment of the display panel, the width of the gap between two adjacent output signal connection pads is 14 microns along the first direction.

In another embodiment of the present disclosure, the display panel includes a display area part and a peripheral area part, wherein the peripheral area part is provided with a chip connection area, and the chip connection area includes an input signal connection pad array and an output signal connection pad array; wherein the input signal connection pad array is disposed on one side of the chip connection area, and the output signal connection pad array is disposed on the other side of the chip connection area; wherein the input signal connection pad array includes at least two input signal connection pads, and the at least two input signal connection pads are arranged in an array along a first direction; wherein the output signal connection pad array includes at least six output signal connection pads, the at least six output signal connection pads are arranged in three columns along a second direction that is perpendicular to the first direction, and the at least six output signal connection pads are arranged in at least two rows along the first direction.

In an embodiment of the display panel, a summation of a width of a gap between two adjacent output signal connection pads and a width of an output signal connection pad is in a range from 20 microns to 36 microns along the first direction.

In an embodiment of the display panel, the summation of the width of the gap between two adjacent output signal connection pads and the width of the output signal connection pad is 28 microns along the first direction.

In an embodiment of the display panel, the width of the gap between two adjacent output signal connection pads is in a range from 10 microns to 18 microns along the first direction.

In an embodiment of the display panel, the width of the gap between two adjacent output signal connection pads is 14 microns along the first direction.

In an embodiment of the display panel, a number of the output signal connection pads in a column of the output signal connection pads is in a range from 900 to 1020 along the first direction.

In an embodiment of the display panel, a number of the output signal connection pads in a column of output signal connection pads is 960 along the first direction.

In an embodiment of the display panel, two sides between the output signal connection pad array and the output signal connection pad array includes a first distance and a second distance along the first direction; wherein the first distance and the second distance are in a range from 100 microns to 180 microns.

In an embodiment of the display panel, the first distance and the second distance are 140 microns.

In an embodiment of the display panel, the display panel further includes a chip, and the chip includes at least two input pins and at least two output pins; wherein the at least two input pins are connected with the input signal connection pad, and the at least two output pins are connected with the output signal connection pad.

In an embodiment of the display panel, a dummy pad array is disposed between the input signal connection pad array and the output signal connection pad array, and the dummy pad array includes at least two redundant connection pads; wherein the at least two redundant connection pads are used for supporting a chip that is fixed to a panel main body of the display panel.

In an embodiment of the display panel, the at least two redundant connection pads are formed during a process of forming the input signal connection pads and/or the output signal connection pads.

In an embodiment of the display panel, an overlapping area of input pins and the input signal connection pad is greater than 1000 square microns; wherein an overlapping area of output pins and the output signal connection pad is greater than 1000 square microns.

In an embodiment of the display panel, a width of the input signal connection pad is in a range from 20 microns to 40 microns; wherein a length of the input signal connection pad is in a range from 120 microns to 160 microns.

In an embodiment of the display panel, a width of the output signal connection pad is in a range from 10 microns to 18 microns; wherein a length of the output signal connection pad is in a range from 100 microns to 160 microns.

In an embodiment of the display panel, at least one alignment mark is further disposed on the chip connection area, the alignment mark is used for fixing a chip with a panel main body, such that the chip is aligned to the panel main body and is arranged at a preset position of the chip connection area of the panel main body.

Compared with the prior art, the chip connection area of the display panel of the present disclosure is provided with an input signal connection pad array and an output signal connection pad array. The input signal connection pad array includes at least two input signal connection pads, and at least two input signal connection pads are arranged in an array along the first direction. The output signal connection pad array includes at least six output signal connection pads. The at least six output signal connection pads are arranged in three columns along a second direction that is perpendicular to the first direction. The at least six output signal connection pads are arranged in at least two rows along the first direction. Therefore, the present disclosure can adapt to various types of chips, and is not limited to a chip with a single pin type.

### BRIEF DESCRIPTION OF THE DRAWINGS

The following embodiments refer to the accompanying drawings for exemplifying specific implementable embodiments of the present disclosure in a suitable computing environment. It should be noted that the exemplary described embodiments are configured to describe and understand the present disclosure, but the present disclosure is not limited thereto.

FIG. 1 is a schematic diagram of a display panel according to one embodiment of the present disclosure.

FIG. 2 is a schematic diagram of a chip connection area in the display panel shown in FIG. 1 according to one embodiment of the present disclosure.

FIG. 3 is a position relationship between two output signal connection pads in the chip connection area shown in FIG. 2 according to one embodiment of the present disclosure.

### DETAILED DESCRIPTION OF THE PREFERRED EMBODIMENTS

The following embodiments refer to the accompanying figures for exemplifying specific implementable embodiments of the present disclosure in a suitable computing environment. It should be noted that the exemplary described embodiments are configured to describe and understand the present disclosure, but the present disclosure is not limited thereto. Directional terms, such as an upper side, a lower side, a front side, a back side, a left side, a right side, an inner side, an outer side, and a lateral side, mentioned in the present disclosure are only for reference. Therefore, the directional terms are used for describing and understanding rather than limiting the present disclosure. In the figures, units having similar structures are used for the same reference numbers.

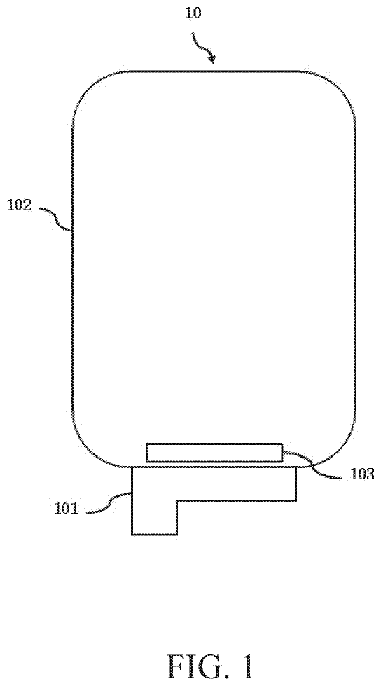

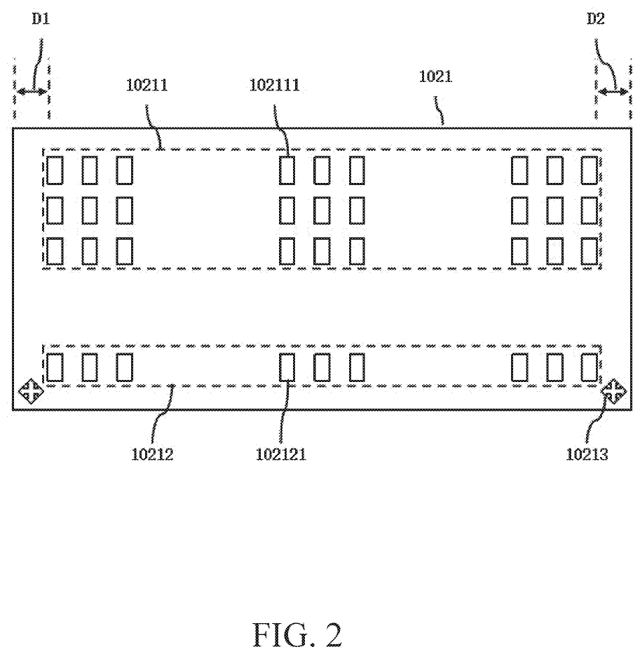

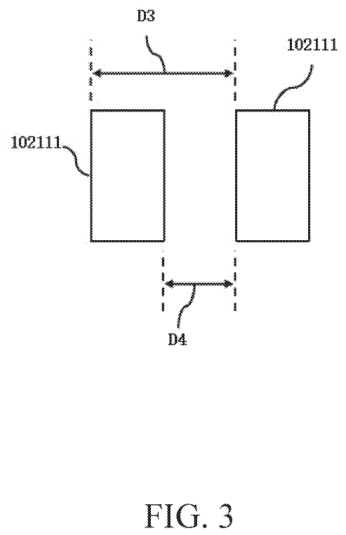

Referring to FIG. 1, FIG. 2 and FIG. 3, FIG. 1 is a schematic diagram of a display panel 10 according to the present disclosure. FIG. 2 is a schematic diagram of a chip connection area 1021 in the display panel 10 shown in FIG. 1. FIG. 3 is a position relationship between two output signal connection pads 102111 in the chip connection area 1021 shown in FIG. 2.

In an embodiment of the present disclosure, the display panel 10 can be an organic light emitting diode (OLED), e.g., an organic light emitting diode display panel and the like.

In an embodiment of the present disclosure, the display panel 10 includes a flexible printed circuit (FPC) 101, a panel main body 102, and a chip, e.g., a driver integrated circuit (DIC) 103. The flexible circuit board 101 is connected with the panel main body 102. The panel main body 102 includes a display area part and a peripheral area part. The peripheral area part is provided with a chip connection area 1021. The chip connection area 1021 includes an input signal connection pad array 10212 and an output signal connection pad array 10211. The chip 103 is arranged on the chip connection area 1021, and the chip 103 is connected with the input signal connection pad array 10212 and the output signal connection pad array 10211.

The input signal connection pad array 10212 is disposed on one side of the chip connection area 1021, and the output signal connection pad array 10211 is disposed on the other side of the chip connection region 1021.

The input signal connection pad array 10212 includes at least two input signal connection pads 102121, and the at least two input signal connection pads 102121 are arranged in an array (e.g., one-dimensional array) along the first direction.

In an embodiment of the present disclosure, the output signal connection pad array 10211 includes at least six output signal connection pads 102111. The at least six output signal connection pads 102111 are arranged in three columns along a second direction that is perpendicular to the first direction. The at least six output signal connection pads 102111 are arranged in at least two rows along the first direction. That is, the at least six output signal connection pads 102111 disposed along the first direction and the second direction are arranged in a two-dimensional array mode.

The input signal connection pad 102121 and the output signal connection pad 102111 are arranged on a substrate or a film layer of the peripheral area part.

In an embodiment of the present disclosure, the first direction is a straight line direction parallel to an intersection of the display area part and the peripheral area parts correspondingly. In another embodiment of the present disclosure, the first direction is a straight line direction perpendicular to an intersection of the display area part and the peripheral area parts correspondingly.

In the first direction, a summation of a width D4 of a gap between two adjacent output signal connection pads 102111 and a width of an output signal connection pad 102111 is defined as D3. In an embodiment, the summation D3 is in a range from 20 microns to 36 microns.

In an embodiment, the summation D3 of the width D4 of the gap between two adjacent output signal connection pads 102111 and the width of the output signal connection pad 102111 is 28 microns along the first direction.

In the first direction, the width D4 of the gap between two adjacent output signal connection pads 102111 is in a range from 10 microns to 18 microns.

In the first direction, the width D4 of the gap between two adjacent output signal connection pads 102111 is 14 microns.

In the first direction, a number of the output signal connection pads 102111 in a column of output signal connection pads 102111 is in a range from 900 to 1020.

In the first direction, a number of the output signal connection pads 102111 in a column of output signal connection pads 102111 is 960.

In the first direction, two sides between the output signal connection pad array 10211 and the output signal connection pad array 10211 includes a first distance D1 and a second distance d2.

In an embodiment, the first distance D1 and the second distance D2 are in a range from 100 microns to 180 microns.

The first distance D1 and the second distance D2 include a distance of 140 microns.

The chip 103 includes at least two input pins and at least two output pins.

The input pins are connected with the input signal connection pad 102121, and the output pins are connected with the output signal connection pad 102111.

At least one alignment mark 10213 is further disposed on the chip connection area 1021. The alignment mark 10213 is used for fixing (e.g., welding) the chip 103 with the panel main body 102, such that the chip 103 is aligned to the panel main body 102 and is arranged at a preset position of the chip connection area 1021 of the panel main body 102. The alignment mark 10213 is arranged at a side portion or a corner of the chip connection area 1021.

In the second direction, there is a preset distance between an edge of the output signal connection pad array 10211 and an edge of the peripheral area part.

A dummy pad array is disposed between the input signal connection pad array 10212 and the output signal connection pad array 10211. The dummy pad array includes at least two redundant connection pads. In an embodiment, the redundant connection pads are formed during a process of forming the input signal connection pads 102121 and/or the output signal connection pads 102111.

The redundant connection pads are used for supporting the chip 103 fixed to the panel main body 102. Specifically, the redundant connection pads support the middle area of the bottom of the chip 103 (e.g., an area between the input pins of the chip 103 and the output pins) so as to improve the connection compactness between the input pins and the input signal connection pads 102121, and/or improve the connection compactness between the output pins and the output signal connection pads 102111, such that the chip 103 can be prevented from being ineffectively supported when the chip 103 may exert force on the input pin and/or the output pin, thereby preventing the input pins and the input signal connection pads 102121 from disconnection, or preventing the output pins and the output signal connection pads 102111 from disconnection.

A width, i.e., a size of the first direction, of the input signal connection pad 102121 is in a range from 20 microns to 40 microns. In an embodiment, the width of the input signal connection pad 102121 is 30 microns. In the first direction, a width of a gap between two adjacent input signal connection pad 102121 is in a range from 10 microns to 20 microns. In an embodiment, the width of the gap between two adjacent input signal connection pad 102121 is 15 microns. A length, i.e., a size of the second direction, of the input signal connection pad 102121 is in a range from 120 microns to 160 microns. In an embodiment, the length of the input signal connection pad 102121 is 140 microns.

A width, i.e., a size of the first direction, of the output signal connection pad 102111 is in a range from 10 microns to 18 microns. In an embodiment, the width of the output signal connection pad 102111 is 14 microns. A length, i.e., a size of the second direction, of the output signal connection pad 102111 is in a range from 100 microns to 160 microns. In an embodiment, the length of the output signal connection pad 102111 is 130 microns.

An overlapping (e.g., contacting) area of the input pin and the input signal connection pad 102121 is greater than 1000 square microns. An overlapping (e.g., contacting) area of the output pin and the output signal connection pad 102111 is greater than 1000 square microns.

According to the present disclosure, the chip connection area of the display panel is provided with an input signal connection pad array and an output signal connection pad array. The input signal connection pad array includes at least two input signal connection pads, and at least two input signal connection pads are arranged in an array along the first direction. The output signal connection pad array includes at least six output signal connection pads. The at least six output signal connection pads are arranged in three columns along a second direction that is perpendicular to the first direction. The at least six output signal connection pads are arranged in at least two rows along the first direction. Therefore, the present disclosure can adapt to various types of chips and is not limited to a chip with a single pin type.

As is understood by a person skilled in the art, the foregoing preferred embodiments of the present disclosure are illustrative rather than limiting of the present disclosure. It is intended that they cover various modifications and similar arrangements be included within the spirit and scope of the present disclosure, the scope of which should be accorded the broadest interpretation so as to encompass all such modifications and similar structures.

What is claimed is:

1. A display panel, comprising a display area part and a peripheral area part, wherein the peripheral area part is provided with a chip connection area, and the chip connection area comprises an input signal connection pad array and an output signal connection pad array;
wherein the input signal connection pad array is disposed on one side of the chip connection area, and the output signal connection pad array is disposed on the other side of the chip connection area;
wherein the input signal connection pad array comprises at least two input signal connection pads, and the at least two input signal connection pads are arranged in an array along a first direction;
wherein the output signal connection pad array comprises at least six output signal connection pads, the at least six output signal connection pads are arranged in three columns along a second direction that is perpendicular to the first direction, and the at least six output signal connection pads are arranged in at least two rows along the first direction;
wherein a summation of a width of a gap between two adjacent output signal connection pads and a width of an output signal connection pad is in a range from 20 microns to 36 microns along the first direction;
wherein a number of the output signal connection pads in a column of the output signal connection pads is in a range from 900 to 1020 along the first direction.

2. The display panel according to claim 1, wherein the summation of the width of the gap between two adjacent output signal connection pads and the width of the output signal connection pad is 28 microns along the first direction.

3. The display panel according to claim 1, wherein the width of the gap between two adjacent output signal connection pads is in a range from 10 microns to 18 microns along the first direction.

4. The display panel according to claim 3, wherein the width of the gap between two adjacent output signal connection pads is 14 microns along the first direction.

5. A display panel, comprising a display area part and a peripheral area part, wherein the peripheral area part is provided with a chip connection area, and the chip connection area comprises an input signal connection pad array and an output signal connection pad array;
wherein the input signal connection pad array is disposed on one side of the chip connection area, and the output signal connection pad array is disposed on the other side of the chip connection area;
wherein the input signal connection pad array comprises at least two input signal connection pads, and the at least two input signal connection pads are arranged in an array along a first direction;
wherein the output signal connection pad array comprises at least six output signal connection pads, the at least six output signal connection pads are arranged in three columns along a second direction that is perpendicular to the first direction, and the at least six output signal connection pads are arranged in at least two rows along the first direction.

6. The display panel according to claim 5, wherein a summation of a width of a gap between two adjacent output signal connection pads and a width of an output signal connection pad is in a range from 20 microns to 36 microns along the first direction.

7. The display panel according to claim 6, wherein the summation of the width of the gap between two adjacent output signal connection pads and the width of the output signal connection pad is 28 microns along the first direction.

8. The display panel according to claim 6, wherein the width of the gap between two adjacent output signal connection pads is in a range from 10 microns to 18 microns along the first direction.

9. The display panel according to claim 8, wherein the width of the gap between two adjacent output signal connection pads is 14 microns along the first direction.

10. The display panel according to claim 5, wherein a number of the output signal connection pads in a column of the output signal connection pads is in a range from 900 to 1020 along the first direction.

11. The display panel according to claim 10, wherein a number of the output signal connection pads in a column of output signal connection pads is 960 along the first direction.

12. The display panel according to claim 5, wherein two sides between the output signal connection pad array and the output signal connection pad array comprises a first distance and a second distance along the first direction;
wherein the first distance and the second distance are in a range from 100 microns to 180 microns.

13. The display panel according to claim 12, wherein the first distance and the second distance are 140 microns.

14. The display panel according to claim 5, wherein the display panel further comprises a chip, and the chip comprises at least two input pins and at least two output pins;
wherein the at least two input pins are connected with the input signal connection pad, and the at least two output pins are connected with the output signal connection pad.

15. The display panel according to claim 5, wherein a dummy pad array is disposed between the input signal connection pad array and the output signal connection pad array, and the dummy pad array comprises at least two redundant connection pads;
wherein the at least two redundant connection pads are used for supporting a chip that is fixed to a panel main body of the display panel.

16. The display panel according to claim 15, wherein the at least two redundant connection pads are formed during a process of forming the input signal connection pads and/or the output signal connection pads.

17. The display panel according to claim 5, wherein an overlapping area of input pins and the input signal connection pad is greater than 1000 square microns;
wherein an overlapping area of output pins and the output signal connection pad is greater than 1000 square microns.

18. The display panel according to claim 5, wherein a width of the input signal connection pad is in a range from 20 microns to 40 microns;
wherein a length of the input signal connection pad is in a range from 120 microns to 160 microns.

19. The display panel according to claim 5, wherein a width of the output signal connection pad is in a range from 10 microns to 18 microns;
wherein a length of the output signal connection pad is in a range from 100 microns to 160 microns.

20. The display panel according to claim 5, wherein at least one alignment mark is further disposed on the chip connection area, the alignment mark is used for fixing a chip with a panel main body, such that the chip is aligned to the panel main body and is arranged at a preset position of the chip connection area of the panel main body.
